(19) United States
(12) Patent Application Publication
(10) Pub. No.: US 2014/0144507 A1
(43) Pub. Date: May 29, 2014

(54) SOLAR CELL AND METHOD OF MANUFACTURING THE SAME

(71) Applicant: SAMSUNG SDI CO., LTD., Yongin-si (KR)

(72) Inventors: Kwang-Soo Huh, Yongin-si (KR); Dong-Ho Lee, Yongin-si (KR); Jae-Ho Shin, Yongin-si (KR)

(73) Assignee: SAMSUNG SDI CO., LTD., Yongin-si (KR)

(21) Appl. No.: 14/033,390

(22) Filed: Sep. 20, 2013

Related U.S. Application Data
(60) Provisional application No. 61/729,513, filed on Nov. 23, 2012.
(60) Provisional application No. 61/751,219, filed on Jan. 10, 2013.

(51) Int. Cl. H01L 31/0328; H01L 31/18

(52) U.S. Cl. CPC H01L 31/0328; H01L 31/1864
USPC 136/262; 136/264; 438/95

(57) ABSTRACT

A solar cell includes a substrate, a rear electrode layer on the substrate, a light-absorption layer on the rear electrode layer, the light-absorption layer including Se and S, and a buffer layer on the light-absorption layer; the light-absorption layer including a depletion region extending from a surface of the light-absorption layer adjacent to the buffer layer, the depletion region having an average S/(Se+S) mole ratio in a range of about 0.10 to about 0.30.

### CROSS-REFERENCE TO RELATED APPLICATION

This application claims priority to and the benefit of U.S. Provisional Application No. 61/729,513, filed on Nov. 23, 2012, and U.S. Provisional Application No. 61/751,219, filed on Jan. 10, 2013. The entire contents of both of these provisional applications are incorporated herein by reference. In addition, the present application incorporated incorporates herein by reference the entire content of U.S. patent application Ser. No. ______, Attorney Docket No. 71589/S744, filed on even date herewith.

### BACKGROUND

1. Field

One or more embodiments of the present invention relate to a solar cell, a method of manufacturing the same.

2. Prior Art

Recently, amid concerns about the depletion of existing energy resources, such as oil or coal, there has been a rising interest in alternative energy. Of alternative energy resources solar cells that convert solar energy directly into electric energy by using semiconductor devices are drawing attention as a next-generation cell.

A solar cell including a basic unit as a diode with a pn function may be classified depending on a material of a light-absorption layer therein.

For example, a solar cell using silicon in the light-absorption layer may be classified as either a crystalline wafer-type solar cell (monocrystalline or polycrystalline), or a thin film type (amorphous or polycrystalline) solar cell. Other representative solar cells are, for example, compound thin film type solar cells including a copper-indium-selenide (CuInSe₂, CIS-based) or cadmium-tellurium (CdTe)-based light-absorption layer, Group III-V solar cells, dye-sensitive solar cells, and organic solar cells.

Of these solar cells, the solar cell including a CIS-based light-absorption layer has an energy band gap (E_{g}) of about 1.04 eV, a high short-circuit current, and a low open-circuit voltage, and thus have a low efficiency. Accordingly, there has been much research into partial substitution of Se with S for increasing the open-circuit voltage of the solar cell while maintaining adhesion between the CIS-based light-absorption layer and a rear electrode layer.

However, addition of excess S may cause severe thermal degradation around a surface of a light-absorption layer of the solar cell even from low-temperature heat, and thus there still are demands for a solar cell with improved resistance to thermal degradation and a method of manufacturing the solar cell.

### SUMMARY

Aspects of embodiments of the present invention are directed to a solar cell having a surface of a light-absorption layer having improved resistance to thermal degradation, and a method of manufacturing the solar cell. Aspects of embodiments of the present invention are also directed toward a solar cell that has an improved open-circuit voltage while maintaining adhesion between a light-absorption layer and a rear-electrode layer, and that has improved resistance to thermal degradation at a surface of the light-absorption layer.

In some embodiments, a solar cell includes a substrate; a rear electrode layer on the substrate; a light-absorption layer on the rear electrode layer, the light-absorption layer including Se and S; and a buffer layer on the light-absorption layer. The light-absorption layer includes a depletion region extending from a surface of the light-absorption layer adjacent to the buffer layer, the depletion region having an average S/(Se+S) mole ratio in a range of about 0.10 to about 0.30.

The depletion region may have an average S/(Se+S) mole ratio in a range of about 0.10 to about 0.27. In some embodiments the depletion region may have an average S/(Se+S) mole ratio in a range of about 0.10 to about 0.25.

The S/(Se+S) mole ratio in the depletion region is greatest at the surface of the light-absorption layer adjacent to the buffer layer and decreases toward a surface of the light-absorption layer adjacent to the rear electrode layer.

The depletion region may include a material having an average composition represented by Formula 1:

Cu(In₁₋ₓGaₓ)(Se_{1-y}S_{y})₂ Formula 1

wherein x is 0.01≦x≦0.25 and y is 0.10≦y≦0.30.

The depletion region may have a thickness of 400 nm or less. In some embodiments, the depletion region may have a thickness of 300 nm or less.

The light-absorption layer may have a thickness in a range of about 0.7 μm to about 2 μm.

In some embodiments, a method of manufacturing a solar sell includes forming a rear electrode layer on a substrate; forming a light-absorption layer on the rear electrode layer, the light absorption layer including Se and S; and forming a buffer layer on the light-absorption layer; where the forming the light-absorption layer includes forming a metal precursor layer, thermally treating the metal precursor layer in a H₂Se atmosphere at a temperature in a range of about 400° C. to about 480° C. to selenize the metal precursor layer, and thermally treating the selenized metal precursor layer in a H₂S atmosphere at a temperature in a range of about 500° C. to about 600° C. for about 30 minutes to about 60 minutes to sulfurize the selenized metal precursor layer.

The thermally treating the selenized metal precursor layer in a H₂S atmosphere may form a depletion region, the depletion region having an average S/(Se+S) mole ratio in a range of about 0.10 to about 0.30.

The depletion region may extend from a surface of the light-absorption layer adjacent to the buffer layer, and the depletion region may have a thickness of 400 nm or less.

The average S/(Se+S) mole ratio in the depletion region may be in a range of about 0.10 to about 0.25.

The depletion region includes a material having an average composition represented by Formula 1:

Cu(In₁₋ₓGaₓ)(Se_{1-y}S_{y})₂ Formula 1

wherein x is 0.01≦x≦0.25 and y is 0.10≦y≦0.30.

The S/(Se+S) mole ratio in the depletion region may decrease as a distance from a surface of the light-absorption layer toward the rear electrode layer increases.

The forming of the metal precursor layer includes sputtering, co-evaporation, electro-deposition, or molecular organic chemical vapor deposition.

The forming of the metal precursor layer may include sputtering copper, indium, and gallium.

In one embodiment, a solar cell including the light-absorption layer has an improved open-circuit voltage while maintaining adhesion between the light-absorption layer and a rear electrode layer, and has improved resistance to thermal degradation.

### BRIEF DESCRIPTION OF THE DRAWINGS

FIG. 1 is a schematic view of a solar cell according to an embodiment of the present invention.

FIG. 2 is a Raman spectrum of a depletion region of a light-absorption layer in the solar cell of Example 1, the depletion region extending from a surface of the light-absorption layer to a depth of 300 nm.

FIG. 3 is a depth profile of CIGS in the depletion region of the light-absorption layer in the solar cell of Example 1 obtained by secondary ion mass spectrometry (SIMS), the depletion region extending from a surface of the light-absorption layer to a depth of 300 nm.

FIG. 4 is a graph of the results of thermal degradation tests with respect to S/(Se+S) mole ratio in solar cells of Examples 1 to 3 and Comparative Examples 1 to 6 after each solar cell was left in a 160° C. oven for about 15 minutes.

FIG. 5 illustrates Arrhenius plots of the solar cell of Example 1 before and after being left in a 160° C. oven for about 15 minutes, obtained by admittance spectroscopy.

FIG. 6 illustrates Arrhenius plots of the solar cell of Comparative Example 3 before and after being left in a 160° C. oven for about 15 minutes, obtained by admittance spectroscopy.

### DETAILED DESCRIPTION

The present invention will now be described more fully with reference to the accompanying drawings, in which embodiments of a solar cell and a method of manufacturing the same are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, elements may be exaggerated, omitted, or schematically illustrated for clarity. It will also be understood that when a layer is referred to as being on another layer or substrate, it can be directly on the other layer or substrate, or intervening layers may also be present.

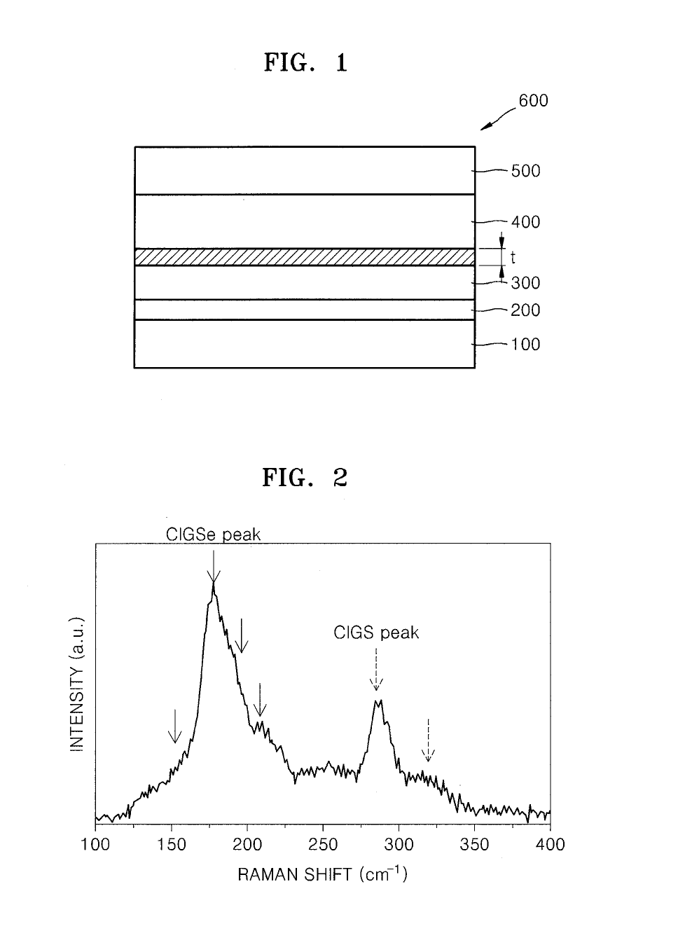

FIG. 1 is a schematic view of a solar cell 600 according to an embodiment of the present invention.

Referring to FIG. 1, the solar cell 600 includes a rear electrode layer 200 disposed on a substrate 100, a light-absorption layer 300 disposed on the rear electrode layer 200, a buffer layer 400 disposed on the light-absorption layer 300, and a transmissive electrode layer 500 disposed on the buffer layer 400.

The substrate 100 may be a glass, ceramic, stainless steel, metal, and/or polymer substrate. For example, the substrate may be a glass substrate, e.g., a sodalime glass substrate or a high-strained point soda glass substrate.

The glass substrate may be, for example, low-iron tempered glass. The low-iron tempered glass may elute sodium (Na) ions at a process temperature of, for example, over about 500° C., thereby further improving the efficiency of the light-absorption layer 300.

The ceramic substrate may be, for example, an alumina substrate. The metal substrate may be a copper tape or the like. The polymer substrate may be a polyimide substrate or the like.

The rear electrode layer 200 may include molybdenum (Mo), aluminum (Al), copper (Cu), or an alloy thereof. The rear electrode layer 200 may be formed of a metal material with high conductivity and high light reflectivity to be able to collect charge generated as a result of a photoelectric effect and to reflect light passing through the light-absorption layer 300 to be reabsorbed by the light-absorption layer 300. For example, the rear electrode layer 200 may include molybdenum (Mo), in consideration of high conductivity, ohmic contact with the light-absorption layer 300, and high-temperature stability in a selenium (Se) atmosphere. The rear electrode layer 200 may have a thickness of from about 200 nm to about 500 nm.

The rear electrode layer 200 may be doped with alkali ions, for example, Na ions. For example, during growing of the light-absorption layer 300, the alkali ions doped on the rear electrode layer 200 may be incorporated into the light-absorption layer 300, and thus provide a structurally improved effect and furthermore, improve conductivity of the light-absorption layer 300. Accordingly, the solar cell 600 may have an increased open-circuit voltage V_{oc} and an increased efficiency. The rear electrode layer 200 may be formed as a multi-layer to ensure or improve adhesion to the substrate 100 and to provide satisfactory resistance characteristics for the rear electrode layer 200.

The light-absorption layer 300 (as a p-type semiconductor layer including a copper-indium-gallium-selenide (Cu(In, Ga)Se₂, CIGS)-based compound obtained by substituting part of indium (In) in a copper-indium-selenium based compound with an amount of gallium (Ga) and part of selenium (Se) with an amount of S) absorbs incident solar light.

The light-absorption layer 300 may include a depletion region extending from a surface thereof to a depth t. An average S/(Se+S) mole ratio in the depletion region may be in a range of about 0.1 to about 0.30. In some embodiments, the average S/(Se+S) mole ratio in the depletion region is in a range of about 0.1 to about 0.27. In some embodiments, the average S/(Se+S) mole ratio in the depletion region is in a range of about 0.1 to about 0.25. In still other embodiments, the average S/(Se+S) mole ratio in the depletion region is in a range of about 0.16 to about 0.25.

The S/(Se+S) mole ratio may be greatest on the surface of the light-absorption layer 300, and may gradually reduce in the depletion region as the distance from the surface increases.

The depth t of the depletion region may vary depending on the content of S. In some embodiments, the depth t is no greater than about 400 nm, and in some embodiments, t is no greater than about 300 nm.

The light-absorption layer 300 may include a depletion region (denoted in FIG. 1 by slash lines) extending from a surface thereof to a depth t. When the depletion region includes excess substituted S, a deep defect may be caused when external heat is applied to the depletion region. This may hinder collecting carriers and cause severe thermal degradation.

In some embodiments, when the average S/(Se+S) mole ratio in the depletion region (denoted in FIG. 1 by slash lines) is within this range (e.g., by controlling the content of S), adhesion between the light-absorption layer 300 and the rear electrode layer 200 is maintained, and allows the rear electrode layer 200 to have a required minimium thickness or greater thickness for adhesion between the light-absorption layer 300 and the rear electrode layer 200. The light-absorption layer 300 also has an increased surface energy band gap (E_{g}) and an improved open-circuit voltage V_{oc}. Accordingly, the solar cell 600 including the light-absorption layer 300 may have improved resistance to thermal degradation.

The depletion region (denoted in FIG. 1 by slash lines) of the light-absorption layer 300 may have an average composition represented by Formula 1 below:

Cu(In₁₋ₓGaₓ)(Se_{1-y}S_{y})₂ Formula 1

In Formula 1, 0.01≦x≦0.25, and 0.1≦y≦0.30. In the depletion region of the light-absorption layer 300, an average S/(Se+S) mole ratio may be in a range of about 0.1 to about 0.30, and an average Ga/(In +Ga) mole ratio may be in a range of about 0.01 to about 0.25. For example, when the average S/(Se+S) mole ratio in the depletion region of the light-absorption layer 300 is in a range of about 0.1 to about 0.27, the average Ga/(In +Ga) mole ratio is in a range of about 0.01 to about 0.27. In some other embodiments, when the average S/(Se+S) mole ratio in the depletion region of the light-absorption layer 300 is in a range of about 0.1 to about 0.25, the average Ga/(In +Ga) mole ratio is in a range of about 0.01 to about 0.2.

The light-absorption layer 300 may have a thickness in a range of about 0.7 μm to about 2 μm. For example, the light-absorption layer 300 has any suitable thickness within this range.

The buffer layer 400 may include CdS, ZnS, ZnO, ZnSe, In₂S₃, ZnₓMg₍₁₋ₓ₎O (where 0<x<1), Zn(S,O), and/or Zn(S,O,OH). The buffer layer 400 may reduce a band gap difference between the light-absorption layer 300, and the transmissive electrode layer 500, which will be described later, and may prevent or reduce recombination of electrons and holes between the light-absorption layer 300 and the transmissive electrode layer 500.

The transmissive electrode layer 500 may include ZnO, ZnO:Al, ZnO:B, indium tin oxide (ITO), and/or indium zinc oxide (IZO). The transmissive electrode layer 500 may be formed of a transparent conductive material and capture charge generated as a result of a photoelectric effect.

Although not illustrated in FIG. 1, an upper surface of the transmissive electrode layer 500 may be textured to reduce reflection of incident solar light and to increase light absorption into the light-absorption layer 300.

According to another embodiment of the present invention, a method of manufacturing a solar cell includes: preparing a substrate with a rear electrode layer thereon; forming a light-absorption layer including Cu, In, Ga, Se, and S on the rear electrode layer; forming a buffer layer on the light-absorption layer; and forming a transmissive electrode layer on the buffer layer. The forming of the light-absorption layer involves thermally treating a metal precursor layer in a H₂Se atmosphere at a temperature of from about 400° C. to about 480° C. for selenization (i.e., to selenize the metal precursor layer), and thermally treating the selenized metal precursor in a H₂S atmosphere at a temperature of from about 500° C. to about 600° C. for about 30 minutes to about 60 minutes for sulfurization (i.e., to sulfurize the selenized metal precursor layer).

First, a substrate 100 with a rear electrode layer 200 on a surface thereof is prepared. The rear electrode layer 200 may be formed on the substrate by, for example, coating a conductive paste on the substrate 100 and thermally treating the same, or by plating. For example, the rear electrode layer 200 may be formed by sputtering using a molybdenum (Mo) target.

Subsequently, the light-absorption layer 300 including Cu, In, Ga, Se, and S is formed on the rear electrode layer 200 (which is on the substrate 100). The light-absorption layer 300 may be formed by co-evaporation in which copper (Cu), indium (In), gallium (Ga), and selenium (Se) are placed in an electric furnace in a vacuum chamber and then heated to evaporate and be formed on the rear electrode layer 200.

In some embodiments, the light-absorption layer 300 may be formed by sputtering/selenization. According to this method, a CIG-based metal precursor layer is formed on the rear electrode layer 200 using copper (Cu), indium (In), and gallium (Ga) metal targets and/or an alloy target thereof, and then thermally treated in a H₂Se gas atmosphere to form a selenized metal precursor layer, which is then further thermally treated in a H₂S gas atmosphere to form the light-absorption layer 300 including Cu, In, Ga, Se, and S. In some embodiments, the light-absorption layer 300 may be formed by electro-deposition, molecular organic chemical vapor deposition (MOCVD), or the like.

For example, forming the light-absorption layer 300 by sputtering/selenization may involve thermally treating a metal precursor layer in a H₂Se atmosphere at a temperature of from about 400° C. to about 480° C. for selenization (i.e., to selenize the metal precursor layer), and thermally treating the selenized metal precursor layer in a H₂S atmosphere at a temperature of from about 500° C. to about 600° C. for about 30 minutes to about 60 minutes for sulfurization (i.e., to sulfurize the selenized metal precursor layer).

In some embodiments, when the temperature and time for sulfurizing the light-absorption layer 300 are within these ranges, the average S/(Se+S) mole ratio in the depletion region (denoted in FIG. 1 by slash lines) of the light-absorption layer 300, which extend from the surface of the light-absorption layer 300 to the depth t, is in a range of about 0.1 to about 0.25.

The S/(Se+S) mole ratio may be greatest on the surface of the light-absorption layer 300, and may gradually decrease in the depletion region as the distance from the surface of the light-absorption layer 300 increases.

The depth t may vary depending on the content of S. In some embodiments, the depth t may be no greater than about 400 nm (e.g., 400 nm or less). In some embodiments, the depth t may be no greater than about 300 nm (e.g., 300 nm or less). In some embodiments, when the average S/(Se+S) mole ratio in the depletion region (denoted in FIG. 1 by slash lines) is within this range (e.g., by controlling the content of S), adhesion between the light-absorption layer 300 and the rear electrode layer 200 is maintained, and allows the rear electrode layer 200 to have a required minimium thickness or greater thickness for adhesion between the light-absorption layer 300 and the rear electrode layer 200. The light-absorption layer 300 also has an increased surface energy band gap (E_{g}) and an improved open-circuit voltage V_{oc}. Accordingly, in some embodiments, the solar cell 600 including the light-absorption layer 300 has improved resistance to thermal degradation.

The depletion region of the light-absorption layer 300 may have an average composition represented by Formula 1 above.

The light-absorption layer 300 may have a thickness of from about 0.7 μm to about 2 μm. For example, the light-absorption layer 300 has any suitable thicknesses within this range.

Subsequently, the buffer layer 400 is formed on the light-absorption layer 300. The buffer layer 400 may reduce a band gap difference between the p-type light-absorption layer 300 and the n-type transmissive electrode layer 500, and suppresses recombination of electrons and holes between the light-absorption layer 300 and the transmissive electrode layer 500. The buffer layer 400 may be formed by chemical bath deposition (CBD), atomic layer deposition (ALD), or ion lay gas reaction (ILGAR).

Next, the transmissive electrode layer 500 is formed on the buffer layer 400. The transmissive electrode layer 500 may be formed, for example, by metalorganic chemical vapor deposition (MOCVD), low-pressure chemical vapor deposition (LPCVD), or sputtering.

Although not illustrated, a top surface of the transmissive electrode layer 500 may be processed by texturing. The texturing is performed by using a physical or chemical method to form an uneven pattern on a surface. When the top surface of the transmissive electrode layer 500 is processed to be rough by texturing, reflection of incident light may be reduced so that the transmissive electrode layer 500 may capture a larger amount of light. This may reduce light loss.

Hereinafter, one or more embodiments of the present invention will be described in further detail with reference to the following examples. These examples are not intended to limit the purpose and scope of the one or more embodiments of the present invention.

### EXAMPLES

### Example 1

A sodalime glass substrate of a thickness of about 1.8 mm with a Mo rear electrode layer was prepared. Sputtering was performed using a CuGa target and an In target to form a metal precursor layer on the Mo rear electrode layer. The metal precursor layer was subjected to selenization in a H₂Se atmosphere at about 420° C. for about 20 minutes, followed by sulfurization in a H₂S atmosphere at about 550° C. for about 60 minutes to form a light-absorption layer including Cu, In, Ga, Se, and S.

The light-absorption layer includes a depletion region extending from an exposed surface of the light-absorption layer to a depth of about 300 nm, wherein an average S/(Se+S) mole ratio in the depletion region is about 0.25. The light-absorption layer has a thickness of about 1.8 μm.

A ZnS buffer layer was formed on the light-absorption layer by chemical bath deposition (CBD) using ammonia water (NH₄OH), zinc sulfide hydrate (ZnSO₄.7H₂O), and thiourea (CS(NH₂)₂). A ZnO transmissive electrode layer was formed on the buffer layer by metal organic chemical vapor deposition (MOCVD), thereby manufacturing a solar cell.

### Example 2

A sodalime glass substrate of a thickness of about 1.8 mm with a Mo rear electrode layer was prepared. Sputtering was performed using a CuGa target and an In target to form a metal precursor layer on the Mo rear electrode layer. The metal precursor layer was subjected to selenization in a H₂Se atmosphere at about 420° C. for about 20 minutes, followed sulfurization in a H₂S atmosphere at about 550° C. for about 50 minutes to form a light-absorption layer including Cu, In, Ga, Se, and S.

The light-absorption layer includes a depletion region extending from an exposed surface of the light-absorption layer to a depth of about 300 nm, wherein an average S/(Se+S) mole ratio in the depletion region is about 0.22. The light-absorption layer has a thickness of about 1.8 μm.

A ZnS buffer layer was formed on the light-absorption layer by chemical bath deposition (CBD) using ammonia water (NH₄OH), zinc sulfide hydrate (ZnSO₄.7H₂O), and thiourea (CS(NH₂)₂). A ZnO transmissive electrode layer was formed on the buffer layer by metal organic chemical vapor deposition (MOCVD), thereby manufacturing a solar cell.

### Example 3

A sodalime glass substrate of a thickness of about 1.8 mm with a Mo rear electrode layer was prepared. Sputtering was performed using a CuGa target and an In target to form a metal precursor layer on the Mo rear electrode layer. The metal precursor layer was subjected to selenization in a H₂Se atmosphere at about 420° C. for about 20 minutes, followed by sulfurization in a H₂S atmosphere at about 550° C. for about 30 minutes to form a light-absorption layer including Cu, In, Ga, Se, and S.

The light-absorption layer includes a depletion region extending from an exposed surface of the light-absorption layer to a depth of about 300 nm, wherein an average S/(Se+S) mole ratio in the depletion region is about 0.16. The light-absorption layer has a thickness of about 1.8 μm.

A ZnS buffer layer was formed on the light-absorption layer by chemical bath deposition (CBD) using ammonia water (NH₄OH), zinc sulfide hydrate (ZnSO₄.7H₂O), and thiourea (CS(NH₂)₂). A ZnO transmissive electrode layer was formed on the buffer layer by metal organic chemical vapor deposition (MOCVD), thereby manufacturing a solar cell.

### Comparative Example 1

A sodalime glass substrate of a thickness of about 1.8 mm with a Mo rear electrode layer was prepared. Sputtering was performed using a CuGa target and an In target to form a metal precursor layer on the Mo rear electrode layer. The metal precursor layer was subjected to selenization in a H₂Se atmosphere at about 420° C. for about 20 minutes, followed by sulfurization in a H₂S atmosphere at about 550° C. for about 20 minutes to form a light-absorption layer including Cu, In, Ga, Se, and S.

The light-absorption layer includes a depletion region extending from an exposed surface of the light-absorption layer to a depth of about 300 nm, wherein an average S/(Se+S) mole ratio in the depletion region is about 0.08. The light-absorption layer has a thickness of about 1.8 μm.

A ZnS buffer layer was formed on the light-absorption layer by chemical bath deposition (CBD) using ammonia water (NH₄OH), zinc sulfide hydrate (ZnSO₄.7H₂O), and thiourea (CS(NH₂)₂). A ZnO transmissive electrode layer was formed on the buffer layer by metal organic chemical vapor deposition (MOCVD), thereby manufacturing a solar cell.

### Comparative Example 2

A sodalime glass substrate of a thickness of about 1.8 mm with a Mo rear electrode layer was prepared. Sputtering was performed using a CuGa target and an In target to form a metal precursor layer on the Mo rear electrode layer. The metal precursor layer was subjected to selenization in a H₂Se atmosphere at about 420° C. for about 20 minutes, followed by sulfurization in a H₂S atmosphere at about 550° C. for about 110 minutes to form a light-absorption layer including Cu, In, Ga, Se, and S.

The light-absorption layer includes a depletion region extending from an exposed surface of the light-absorption layer to a depth of about 300 nm, wherein an average S/(Se+S) mole ratio in the depletion region is about 0.38. The light-absorption layer has a thickness of about 1.8 μm.

A ZnS buffer layer was formed on the light-absorption layer by chemical bath deposition (CBD) using ammonia water (NH₄OH), zinc sulfide hydrate (ZnSO₄.7H₂O), and thiourea (CS(NH₂)₂). A ZnO transmissive electrode layer was formed on the buffer layer by metal organic chemical vapor deposition (MOCVD), thereby manufacturing a solar cell.

### Comparative Example 3

A sodalime glass substrate of a thickness of about 1.8 mm with a Mo rear electrode layer was prepared. Sputtering was performed using a CuGa target and an In target to form a metal precursor layer on the Mo rear electrode layer. The metal precursor layer was subjected to selenization in a H₂Se atmosphere at about 420° C. for about 20 minutes, followed by sulfurization in a H₂S atmosphere at about 550° C. for about 90 minutes to form a light-absorption layer including Cu, In, Ga, Se, and S.

The light-absorption layer includes a depletion region extending from a surface of the light-absorption layer to a depth of about 300 nm, wherein an average S/(Se+S) mole ratio in the depletion region is about 0.34. The light-absorption layer has a thickness of about 1.8 μm.

A ZnS buffer layer was formed on the light-absorption layer by chemical bath deposition (CBD) using ammonia water (NH₄OH), zinc sulfide hydrate (ZnSO₄.7H₂O), and thiourea (CS(NH₂)₂). A ZnO transmissive electrode layer was formed on the buffer layer by metal organic chemical vapor deposition (MOCVD), thereby manufacturing a solar cell.

### Comparative Example 4

A sodalime glass substrate of a thickness of about 1.8 mm with a Mo rear electrode layer was prepared. Sputtering was performed using a CuGa target and an In target to form a metal precursor layer on the Mo rear electrode layer. The metal precursor layer was subjected to selenization in a H₂Se atmosphere at about 420° C. for about 15 minutes, followed by sulfurization in a H₂S atmosphere at about 550° C. for about 90 minutes to form a light-absorption layer including Cu, In, Ga, Se, and S.

The light-absorption layer includes a depletion region extending from an exposed surface of the light-absorption layer to a depth of about 300 nm, wherein an average S/(Se+S) mole ratio in the depletion region is about 0.35. The light-absorption layer has a thickness of about 1.8 μm.

A ZnS buffer layer was formed on the light-absorption layer by chemical bath deposition (CBD) using ammonia water (NH₄OH), zinc sulfide hydrate (ZnSO₄.7H₂O), and thiourea (CS(NH₂)₂). A ZnO transmissive electrode layer was formed on the buffer layer by metal organic chemical vapor deposition (MOCVD), thereby manufacturing a solar cell.

### Comparative Example 5

A sodalime glass substrate of a thickness of about 1.8 mm with a Mo rear electrode layer was prepared. Sputtering was performed using a CuGa target and an In target to form a metal precursor layer on the Mo rear electrode layer. The metal precursor layer was subjected to selenization in a H₂Se atmosphere at about 420° C. for about 20 minutes, followed by sulfurization in a H₂S atmosphere at about 550° C. for about 100 minutes to form a light-absorption layer including Cu, In, Ga, Se, and S.

The light-absorption layer includes a depletion region extending from an exposed surface of the light-absorption layer to a depth of about 300 nm, wherein an average S/(Se+S) mole ratio in the depletion region is about 0.37. The light-absorption layer has a thickness of about 1.8 μm.

A ZnS buffer layer was formed on the light-absorption layer by chemical bath deposition (CBD) using ammonia water (NH₄OH), zinc sulfide hydrate (ZnSO₄.7H₂O), and thiourea (CS(NH₂)₂). A ZnO transmissive electrode layer was formed on the buffer layer by metal organic chemical vapor deposition (MOCVD), thereby manufacturing a solar cell.

### Comparative Example 6

A sodalime glass substrate of a thickness of about 1.8 mm with a Mo rear electrode layer was prepared. Sputtering was performed using a CuGa target and an In target to form a metal precursor layer on the Mo rear electrode layer. The metal precursor layer was subjected to selenization in a H₂Se atmosphere at about 420° C. for about 20 minutes, followed by sulfurization in a H₂S atmosphere at about 550° C. for about 80 minutes to form a light-absorption layer including Cu, In, Ga, Se, and S.

The light-absorption layer includes a depletion region extending from an exposed surface of the light-absorption layer to a depth of about 300 nm, wherein an average S/(Se+S) mole ratio in the depletion region is about 0.32. The light-absorption layer has a thickness of about 1.8 μm.

A ZnS buffer layer was formed on the light-absorption layer by chemical bath deposition (CBD) using ammonia water (NH₄OH), zinc sulfide hydrate (ZnSO₄.7H₂O), and thiourea (CS(NH₂)₂). A ZnO transmissive electrode layer was formed on the buffer layer by metal organic chemical vapor deposition (MOCVD), thereby manufacturing a solar cell.

### Evaluation Example 1

### Raman Spectrometry Test

The solar cell of Example 1 was tested using a Raman spectrometer (available from Renishaw, United Kingdom), in which the depletion region of the light-absorption layer ranging from the surface thereof to the depth of about 300 nm was irradiated with laser light of about 633 nm. The results are shown in FIG. 2.

Referring to FIG. 2, CIGSe peaks appear in the range of 150 cm⁻¹ to 210 cm⁻¹′ and CIGS peaks appear in the range of 275 cm⁻¹ to 340 cm⁻¹. The S/(Se+S) mole ratio was calculated using Equation 1 below.

S/(Se+S)mole ratio=(Area of CIGS peaks)/(Area of CIGSe peaks+Area of CIGS peaks) Equation 1

Referring to FIG. 2, the depletion region of the light-absorption layer in the solar cell of Example 1, extending from the surface of the light-absorption layer to a depth of about 300 nm, was found to have a S/(Se+S) mole ratio of about 0.25.

### Evaluation Example 2

### Secondary Ion Mass Spectrometry (SIMS) Test

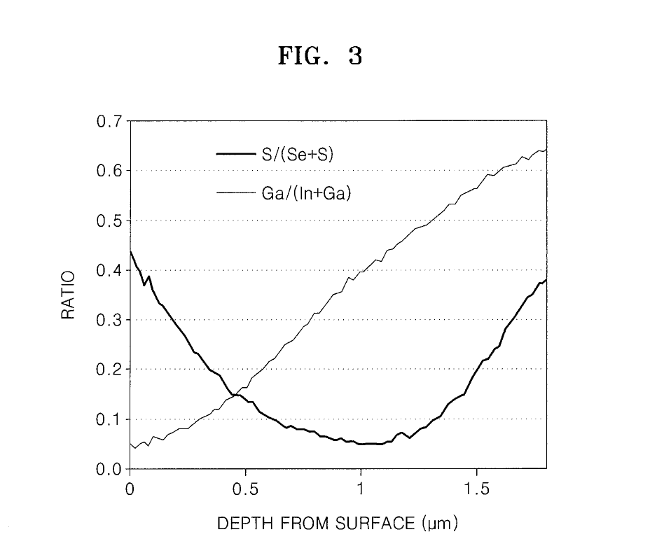

The depletion region of the light-absorption layer in the solar cell of Example 1, extending from the surface of the light-absorption layer to the depth of about 300 nm, was analyzed by secondary ion mass spectrometry (SIMS) using an analyzer (IMS-6f Magnetic Sector SIMS, available from CAMECA, France). The results are shown in FIG. 3.

Experimental conditions for the SIMS measurement were as follows:

Primary ion conditions: Cs⁺ ions, 5 keV, about 80 nA

Irradiation area: Raster Size (about 200 μm×200 μm)

Analysis area: about 30 μm (φ)

Polarity of secondary ions: Negative

Charge compensation: Done

Based on the SIMS results, S/(S+Se) and Ga/(In +Ga) mole ratios were calculated, each as an average from multiple measurement sites.

Referring to FIG. 3, the depletion region of the light-absorption layer in the solar cell of Example 1, extending from the surface of the light-absorption layer to a depth of about 300 nm, was found to have an average S/(Se+S) mole ratio of about 0.25, and an average Ga/(In +Ga) mole ratio of about 0.08.

### Evaluation Example 3

### Thermal Degradation Test

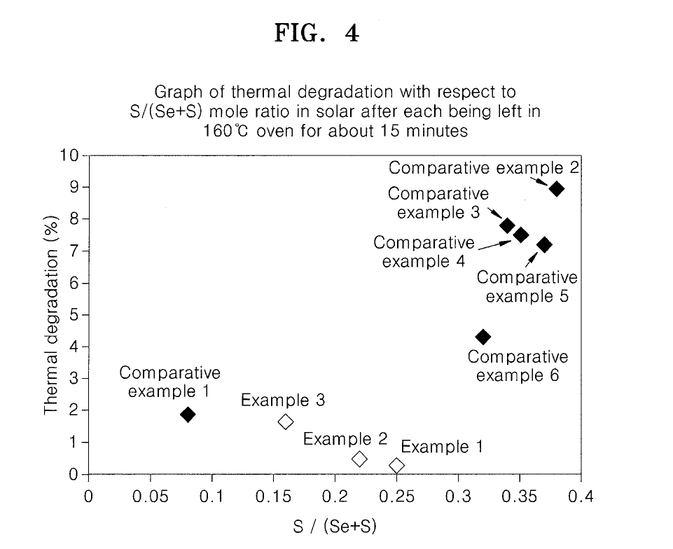

Thermal degradation tests of the solar cells of Examples 1 to 3 and Comparative Examples 1 to 6 were conducted by leaving the solar cells in an oven at about 160° C. for about 15 minutes. The results are shown in FIG. 4 and Table 1 below.

TABLE 1

| | S/(Se + S) mole | Thermal degradation |
|---|---|---|
| Example | ratio | rate (%) |
| Example 1 | 0.25 | 0.26 |
| Example 2 | 0.22 | 0.45 |
| Example 3 | 0.16 | 1.6 |
| Comparative Example 1 | 0.08 | 1.8 |
| Comparative Example 2 | 0.38 | 8.9 |
| Comparative Example 3 | 0.34 | 7.8 |
| Comparative Example 4 | 0.35 | 7.5 |
| Comparative Example 5 | 0.37 | 7.2 |
| Comparative Example 6 | 0.32 | 4.3 |

Referring to FIG. 4 and Table 1, the solar cells of Examples 1 to 3 were found to have lower thermal degradation rates than the solar cells of Comparative Examples 1 to 6. Although the solar cell of Comparative Example 1 had a relatively smaller difference in thermal degradation rate compared to the solar cell of Example 3, i.e., about 0.2% higher, the solar cell of Comparative Example 1 had too low of a S/(Se+S) mole ratio (i.e., less than 0.1), and thus adhesion between the CIGS-based light-absorption layer and the rear electrode layer in the solar cell of Comparative Example 1 was weak due to a short sulfurization time, and thus the rear electrode layer in the solar cell of Comparative Example 1 is little formed or has a very thin thickness. The CIGS-based light-absorption layer (300) had a reduced surface energy band gap (E_{g}), which leads to deterioration in open-circuit voltage (V_{oc}).

### Evaluation Example 4

### Admittance Spectroscopy Test

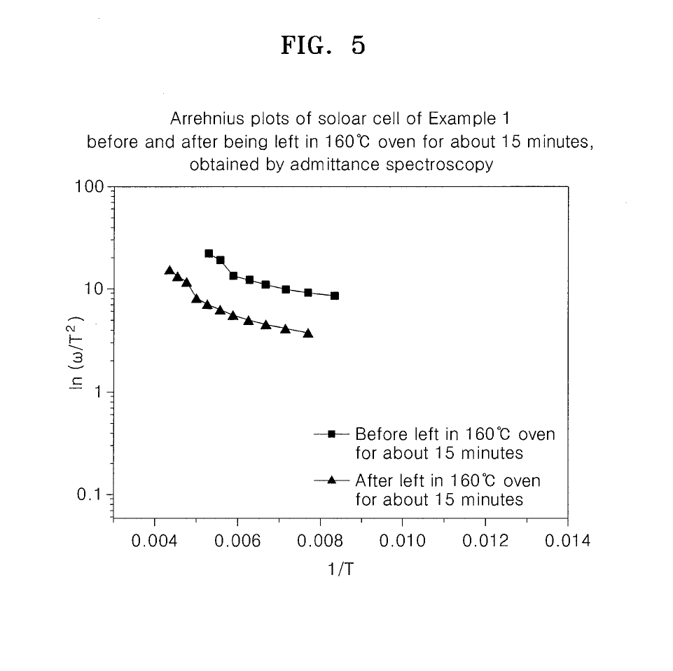

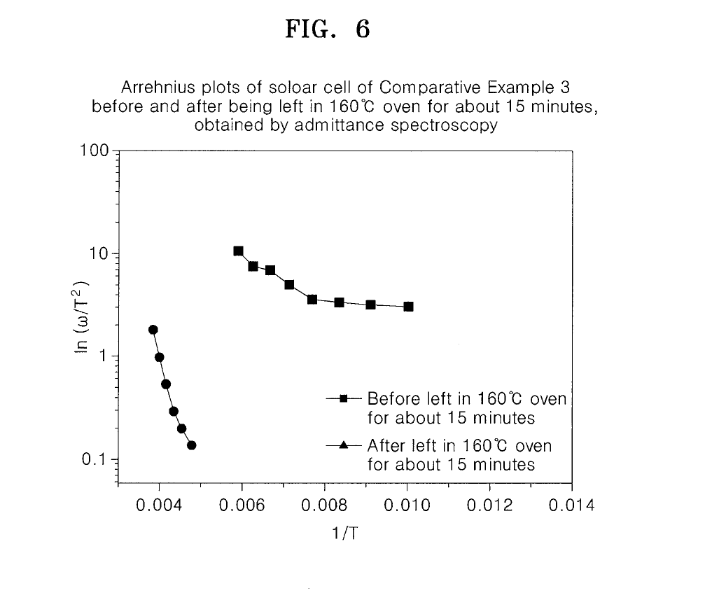

Admittance spectroscopy tests of the solar cells of Example 1 and Comparative Example 3 were conducted before and after the solar cells were left in a 160° C. oven for about 15 minutes to obtain Arrhenius plots of the solar cells. The results are shown in FIGS. 5 and 6 and Table 2 below.

The admittance spectroscopy test was conducted using an admittance spectrometer (B1500A, available from Agilent, Calif., U.S.) in a frequency range of 1 kHz to 1 MHz at a temperature of about 80 K to about 360 K.

The Arrhenius plots were obtained using Equation 2 below, and a slope of In(ω/T²) versus 1/T indicates a defect activation energy.

ω=2ε₀T²exp[−Eₐ/kT] Equation 2

In Equation 2, ω is a frequency of 1 kHz to 1 MHz, Eₐ is a defect activation energy, and ε₀ is a pre-exponential factor as a y-intercept in the graph of FIG. 5.

TABLE 2

| | Eₐ(meV) before and after being left |
|---|---|
| Example | in 160° C. oven for 15 min |
| Example 1 | 54.3, 62.3 |
| Comparative Example 3 | 49.1, 242.4 |

Referring to FIGS. 5 and 6 and Table 2, almost no change in Eₐ after being left in 160° C. oven for about 15 minutes was found in the solar cell of Example 1, while there was a severe increase in Eₐ after being left in 160° C. oven for about 15 in the solar cell of Comparative Example 1.

These results indicate that the solar cell of Example 1 may have a relatively shallow defect depth even after the exposure to external heat, compared with the solar cell of Comparative Example 3, which had a greater defect depth after being exposed to external heat.

While the present invention has been particularly shown and described with reference to embodiments thereof, it will be understood by those of ordinary skill in the art that various changes in form and details may be made therein without departing from the spirit and scope of the present invention as defined by the following claims, and equivalents thereof.

Explanation of Reference Numerals

| | |
|---|---|
| 100: substrate | 200: rear electrode layer |
| 300: light-absorption layer | 400: buffer layer |
| 500: transmissive electrode layer | 600: solar cell |

What is claimed is:

1. A solar cell comprising:
a substrate;
a rear electrode layer on the substrate;
a light-absorption layer on the rear electrode layer, the light-absorption layer comprising Se and S; and
a buffer layer on the light-absorption layer; and
wherein the light-absorption layer comprises a depletion region extending from a surface of the light-absorption layer adjacent to the buffer layer, the depletion region having an average S/(Se+S) mole ratio in a range of about 0.10 to about 0.30.

2. The solar cell of claim 1, wherein the depletion region has an average S/(Se+S) mole ratio in a range of about 0.10 to about 0.27.

3. The solar cell of claim 1, wherein the depletion region has an average S/(Se+S) mole ratio in a range of about 0.10 to about 0.25.

4. The solar cell of claim 1, wherein the S/(Se+S) mole ratio in the depletion region is greatest at the surface of the light-absorption layer adjacent to the buffer layer and decreases toward a surface of the light-absorption layer adjacent to the rear electrode layer.

5. The solar cell of claim 1, wherein the depletion region comprises a material having an average composition represented by Formula 1:
Cu(In₁₋ₓGaₓ)(Se_{1-y}S_{y})₂ Formula 1
wherein x is 0.01≦x≦0.25 and y is 0.10≦y≦0.30.

6. The solar cell of claim 1, wherein the depletion region has a thickness of 400 nm or less.

7. The solar cell of claim 1, wherein the depletion region has a thickness of 300 nm or less.

8. The solar cell of claim 1, wherein the light-absorption layer has a thickness in a range of about 0.7 μm to about 2 μm.

9. A method of manufacturing a solar sell comprises:
forming a rear electrode layer on a substrate;
forming a light-absorption layer on the rear electrode layer, the light absorption layer comprising Se and S; and
forming a buffer layer on the light-absorption layer;
wherein the forming the light-absorption layer comprises forming a metal precursor layer, thermally treating the metal precursor layer in a H₂Se atmosphere at a temperature in a range of about 400° C. to about 480° C. to selenize the metal precursor layer, and thermally treating the selenized metal precursor layer in a H₂S atmosphere at a temperature in a range of about 500° C. to about 600° C. for about 30 minutes to about 60 minutes to sulfurize the selenized metal precursor layer.

10. The method of claim 9, wherein the thermally treating the selenized metal precursor layer in a H₂S atmosphere forms a depletion region, the depletion region having an average S/(Se+S) mole ratio in a range of about 0.10 to about 0.30.

11. The method of claim 10, wherein the depletion region extends from a surface of the light-absorption layer adjacent to the buffer layer, and the depletion region has a thickness of 400 nm or less.

12. The method of claim 10, wherein the average S/(Se+S) mole ratio in the depletion region is in a range of about 0.10 to about 0.25.

13. The method of claim 10, wherein the depletion region comprises a material having an average composition represented by Formula 1:
Cu(In₁₋ₓGaₓ)(Se_{1-y}S_{y})₂ Formula 1
wherein x is 0.01≦x≦0.25 and y is 0.10≦y≦0.30.

14. The method of claim 10, wherein a S/(Se+S) mole ratio in the depletion region decreases as a distance from a surface of the light-absorption layer toward the rear electrode layer increases.

15. The method of claim 9, wherein the forming of the metal precursor layer comprises sputtering, co-evaporation, electro-deposition, or molecular organic chemical vapor deposition.

16. The method of claim 9, wherein the forming of the metal precursor layer comprises sputtering copper, indium, and gallium.
